(19) United States
(12) Patent Application Publication
(10) Pub. No.: US 2011/0030782 A1
(43) Pub. Date: Feb. 10, 2011

(54) SOLAR CELL AND METHOD FOR MANUFACTURING THE SAME

(75) Inventor: Min-Seok OH, Yongin-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si (KR)

(21) Appl. No.: 12/645,762

(22) Filed: Dec. 23, 2009

(30) Foreign Application Priority Data
Aug. 10, 2009 (KR) 10-2009-0073483

(51) Int. Cl. H01L 31/00; H01L 31/0232

(52) U.S. Cl. 136/258; 136/261; 438/72; 257/E31.127; 977/773

(57) ABSTRACT

A solar cell includes a semiconductor substrate, a p-type organic semiconductor layer disposed on a first region of a rear surface of the semiconductor substrate, an n-type semiconductor layer disposed on a second region of the rear surface of the semiconductor substrate which is different than the first region, a rear electrode disposed on a rear surface of the p-type organic semiconductor layer, a first grid electrode disposed on a rear surface of the rear electrode, and a second grid electrode disposed on a rear surface of the n-type semiconductor layer.

This application claims priority to Korean Patent Application No. 10-2009-0073483 filed Aug. 10, 2009, and all the benefits accruing therefrom under 35 U.S.C. §119, the entire contents of which are incorporated herein by reference.

### BACKGROUND OF THE INVENTION

1. Field of the Invention

The invention relates to a solar cell and a method for manufacturing the same.

2. Description of the Related Art

A solar cell is a photoelectric conversion device transforming solar energy into electrical energy, and it has been drawing much attention as an infinite but pollution-free next-generation energy source.

A solar cell includes a p-type semiconductor and an n-type semiconductor, and produces electrical energy by transferring electrons and holes to the n-type and p-type semiconductors, respectively, and then collecting electrons and holes in each electrode, when an electron-hole pair (“EHP”) is produced by solar light energy absorbed in a photoactive layer inside the semiconductors.

As shown in FIG. 6, the solar cell 10 of the prior art has a general structure in which a p-type semiconductor layer 3 is disposed on a front surface of an n-type silicon semiconductor substrate 1, a transparent oxide conductive layer 5 and a grid electrode 7 are further disposed thereon, and a metal rear electrode 9 is disposed on a rear surface of the n-type silicon semiconductor substrate 1. The grid electrode 7 disposed on the front surface of the n-type silicon semiconductor substrate 1, occupies about 5% to about 7% of a total planar light receiving area of incident light, causing a shadowing loss to deteriorate the efficiency of the solar cell.

### BRIEF SUMMARY OF THE INVENTION

An exemplary embodiment of the invention provides a solar cell having excellent efficiency and no shadowing loss.

Another exemplary embodiment of the invention provides a method of manufacturing a solar cell, through which a solar cell having high efficiency is provided by a simple process, and workability is improved.

According to an exemplary embodiment, provided is a solar cell that includes a semiconductor substrate, a p-type organic semiconductor layer disposed on one region of a rear surface of the semiconductor substrate, an n-type semiconductor layer disposed on another region of the rear surface of the semiconductor substrate, a rear electrode disposed on the p-type organic semiconductor layer, a first grid electrode disposed on the rear electrode, and a second grid electrode disposed on the n-type semiconductor layer.

The semiconductor substrate may include crystalline silicon, and the crystalline silicon may include a monocrystalline or polysilicon wafer. The semiconductor substrate may include a textured front surface.

The p-type organic semiconductor layer may include a p-type polymer semiconductor or a p-type organic monomolecular compound selected from the group consisting of a polyphenylene-based polymer, a polythiophene-based polymer, a polyfluorene-based polymer, a derivative thereof, a copolymer, and a mixture thereof. The p-type organic semiconductor layer may include poly(p-phenylenevinylene) (“PPV”), poly[2-methoxy-5-(2′-ethyl-hexyloxy)-1,4-phenylene-vinylene] (“MEH-PPV”), poly(2-methoxy-5-(3,7-dimethyloctyloxy)-1,4-phenylene-vinylene) (“MDMO-PPV”), polythiophene (“PT”), poly(3,4-ethylenedioxythiophene) (“PEDOT”), poly(3-alkylthiophene), fluorine copolymer APFO-Green1, fluorine copolymer APFO-Green2, poly[2,7-(9,9′-dihexylfluorene)-alt-2,3-dimethyl-5,7-dithien-2-yl-2,1,3-benzothiadiazole] (“PFDTBT”), copper phthalocyanine (“CuPc”), zinc phthalocyanine (“ZnPc”), a derivative thereof, and a mixture thereof.

The n-type semiconductor layer may include an n-type organic semiconductor compound, an n-type inorganic nanoparticle semiconductor, or a combination thereof. The n-type organic semiconductor compound may include fullerene, a fullerene derivative, perylene, 3,4,9,10-perylene tetracarboxylic bis-benzimidazole (“PTCBI”), a derivative thereof, and a mixture thereof. The n-type inorganic nanoparticle semiconductor includes a group II-VI semiconductor compound such as cadmium sulfide (“CdS”), cadmium telluride (“CdTe”), cadmium selenide (“CdSe”), zinc oxide (“ZnO”), zinc selenide (“ZnSe”), zinc sulfide (“ZnS”), and zinc telluride (“ZnTe”), and combinations thereof.

The rear electrode may include a conductive material having a work function of about 4.3 electron volts (eV) or more. The first grid electrode may include silver (Ag), copper (Cu), and a combination thereof. The second grid electrode may include a metal having a work function of about 4.2 eV or less, such as lithium (Li), lithium doped aluminum (“Li:Al”), lithium fluoride doped aluminum (“LiF:Al”), silver (Ag), aluminum (Al), calcium (Ca), magnesium (Mg), magnesium doped lithium (“Mg:Li”), magnesium doped silver (“Mg:Ag”), and the like.

The semiconductor substrate may further include an anti-reflective coating (“ARC”) on its front surface. The anti-reflective coating may include silicon nitride (“SiNₓ”), silicon oxide (“SiOₓ”), silicon oxynitride (“SiOₓN_{y}”), titanium oxide (TiO₂), aluminum oxide (Al₂O₃), magnesium oxide (MgO), cerium oxide (CeO₂), and combinations thereof.

The solar cell may further include a first passivation layer between the semiconductor substrate and the p-type organic semiconductor layer, and the semiconductor substrate and the n-type semiconductor layer. The solar cell may further include a second passivation layer between the semiconductor substrate and the anti-reflective coating. The first and second passivation layers may include an inorganic oxide of intrinsic amorphous silicon, or Al₂O₃.

The solar cell may further include an insulation layer between the p-type organic semiconductor layer and the n-type semiconductor layer. The insulation layer may include an acryl-based or siloxane-based organic insulating material.

According to another exemplary embodiment, provided is a method of manufacturing a solar cell, the method including providing a semiconductor substrate, providing a p-type organic semiconductor layer on one region of a rear surface of the semiconductor substrate and an n-type semiconductor layer on another region different from the one region, providing a rear electrode and a first grid electrode on the p-type organic semiconductor layer, and providing a second grid electrode on the n-type semiconductor layer.

The manufacturing method may further include providing a passivation layer and an anti-reflective coating on a front surface of semiconductor substrate, before the providing a p-type organic semiconductor layer on one region of the rear surface of the semiconductor substrate and the providing a n-type semiconductor layer on another region thereof. The method may further include providing a first passivation layer, before the providing a p-type organic semiconductor layer on one region of the rear surface of the semiconductor substrate and the providing an n-type semiconductor layer on the other region. In addition, after patterning an insulation layer on the semiconductor substrate, a p-type organic semiconductor layer and an n-type semiconductor layer may be formed.

The p-type organic semiconductor layer, the n-type semiconductor layer, the rear electrode, the first and second grid electrodes, and the insulation layer may be coated in accordance with a wet process such as gravure printing, offset printing, screen printing, Inkjet printing, spin coating, spray coating, and the like.

### BRIEF DESCRIPTION OF THE DRAWINGS

The above and other features of this disclosure will become more apparent by describing in further detail exemplary embodiments thereof with reference to the accompanying drawings, in which:

FIG. 1 is a schematic cross-sectional view of an exemplary embodiment of a solar cell, according to the invention.

FIG. 2 is a schematic cross-sectional view of another exemplary embodiment of a solar cell, according to the invention.

FIG. 3 is a schematic cross-sectional view of another exemplary embodiment of a solar cell, according to the invention.

FIG. 4 is a flowchart of an exemplary embodiment of a method for manufacturing a solar cell, according to the invention.

FIG. 5 is a flowchart of another exemplary embodiment of a method for manufacturing a solar cell, according to the invention.

FIG. 6 is a view showing a general structure of a solar cell of the prior art.

### DETAILED DESCRIPTION OF THE INVENTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. As used herein, the term “and/or” includes any and all combinations of one or more of the associated listed items.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “front” or “rear” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “front” side of other elements would then be oriented on “rear” side of the other elements. The exemplary term “front,” can therefore, encompasses both an orientation of “front” and “rear,” depending on the particular orientation of the figure.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

As used herein, when a definition is not otherwise provided, the term “alkyl” refers to a C1 to C10 alkyl.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, referring to drawings, exemplary embodiments of a solar cell, according to the invention are described.

In order to prevent the efficiency deterioration of the solar cell, it has been suggested to provide different kinds of electrodes on the rear surface of the substrate. When the different kinds of electrodes are disposed on the rear surface of the substrate, all of the p-type silicon, the n-type silicon, and the transparent oxide (“TCO”) conductive layer are disposed on the rear surface thereof in accordance with a photolithography process. However, the photolithography process may make the process complicated and may cause an electrical short circuit between the p-type electrode and the n-type electrode, so as to deteriorate passivation quality.

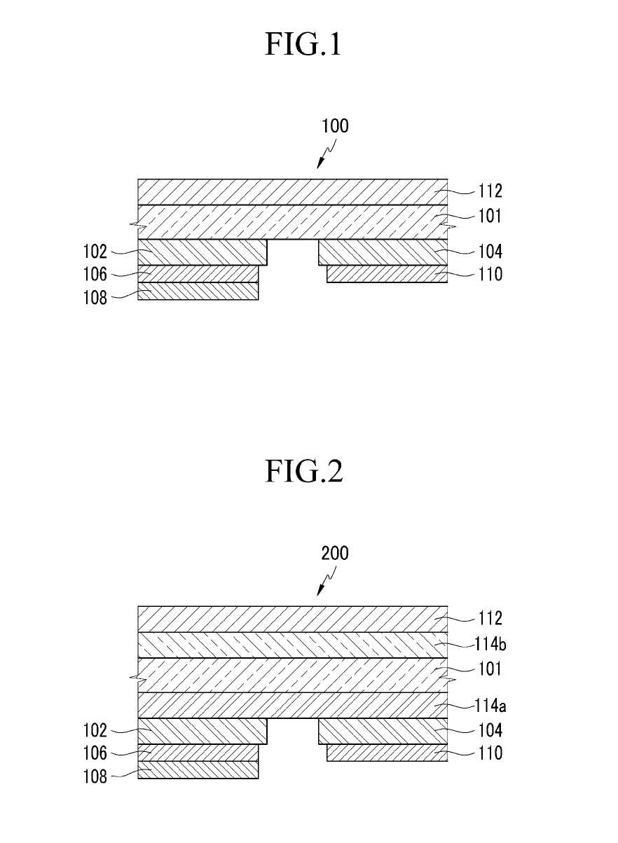

FIG. 1 is a schematic cross-sectional view of an exemplary embodiment of a solar cell 100, according to the invention. Solar light is incident from a front side of the solar cell 100, and solar light may not be incident from a rear side of the solar cell 100.

Referring to FIG. 1, the solar cell 100 includes a semiconductor substrate 101, a p-type organic semiconductor layer 102 disposed on one (e.g., first) region of a rear surface of the semiconductor substrate 101 and an n-type semiconductor layer 104 disposed on another (e.g., second) region of the rear surface of the semiconductor substrate 101 not including the first region, a rear electrode 106 disposed on the p-type organic semiconductor layer 102, a first grid electrode 108 disposed on the rear electrode 106, and a second grid electrode 110 disposed on the n-type semiconductor layer 104.

In a plan view of the solar cell 100, a third (e.g., remaining) region of the rear surface of the semiconductor substrate 101 is not overlapped by any of the p-type organic semiconductor layer 102, the n-type semiconductor layer 104, the rear electrode 106, the first grid electrode 108 and the second grid electrode 110. The p-type organic semiconductor layer 102, the rear electrode 106 and the first grid electrode 108 are overlapped with each other within the first region of the semiconductor substrate 101, in the plan view of the solar cell 100. The n-type semiconductor layer 104 and the second grid electrode 110 are overlapped with each other within the second region of the semiconductor substrate 101, and spaced apart from the first region, in the plan view of the solar cell 100. The first grid electrode 108 and/or the second grid electrode 110 may define the rearmost layer of the solar cell 100.

In an exemplary embodiment, the semiconductor substrate 101 may include crystalline silicon, and the crystalline silicon may include a mono- or poly-silicon wafer.

A front surface of semiconductor substrate 101 may be subject to a surface-texturing treatment, in a process of manufacturing the solar cell 100. The surface-textured semiconductor substrate 101 may include a structure of pyramidal protrusions and depressions, or of a porous honeycomb. The surface-textured semiconductor substrate 101 may increase the light absorptivity by increasing the surface area of the front surface, and improve the efficiency of the solar cell by decreasing reflectivity.

The p-type organic semiconductor layer 102 is disposed on the one region of the rear surface of the semiconductor substrate 101, and the n-type semiconductor layer 104 is disposed on the second region of the semiconductor substrate 101 not including the first region. The first and second regions are spaced apart from each other in the plan view of the solar cell 100, for example, by the third remaining region of the rear surface of the semiconductor substrate 101.

In an exemplary embodiment, the p-type organic semiconductor layer 102 may include a p-type polymer semiconductor or a p-type organic monomolecular compound having hole mobility of about 1.0×10⁻⁶ square centimeter per volt second (cm²/Vs) or more. The p-type polymer semiconductor may include a polyphenylene-based polymer, a polythiophene-based polymer, a polyfluorene-based polymer, a derivative thereof, a copolymer thereof, a mixture thereof, and the like. In exemplary embodiments, the p-type polymer semiconductor may include poly[2-methoxy-5-(2′-ethyl-hexyloxy)-1,4-phenylene-vinylene] (“MEH-PPV”), poly(2-methoxy-5-(3,7-dimethyloctyloxy)-1,4-phenylene-vinylene) (“MDMO-PPV”), polythiophene (“PT”), poly(3,4-ethylenedioxythiophene) (“PEDOT”), poly(3-hexylthiophene) (“P3HT”), and a poly(3-alkylthiophene) such as poly(3-octylthiophene), polyfluorene copolymer APFO-Green1, polyfluorene copolymer APFO-Green2, poly[2,7-(9,9′-dihexylfluorene)-alt-2,3-dimethyl-5,7-dithien-2-yl-2,1,3-benzothiadiazole] (“PFDTBT”), and the like. The p-type organic monomolecular compound may include a phthalocyanine-based material such as copper phthalocyanine (“CuPc”), zinc phthalocyanine (“ZnPc”), and the like.

In an exemplary embodiment, the n-type semiconductor layer 104 includes an n-type organic semiconductor compound, an n-type inorganic nanoparticle semiconductor, or combinations thereof having electron mobility of 1.0×10⁻⁶ cm²/Vs or more.

The n-type organic semiconductor compound may include fullerene (“C60”); a fullerene derivative such as 1-(3-methoxy-carbonyl)propyl-1-phenyl-(6,6)C61 (“PCBM”), C71-PCBM, C84-PCBM, bis-PCBM, and the like, perylene, 3,4,9,10-perylene tetracarboxylic bis-benzimidazole (“PTCBI”), a derivative thereof, or a mixture thereof. The n-type inorganic nanoparticle semiconductor may include inorganic nanoparticles except silicon, for example a group II-VI semiconductor compound such as cadmium sulfide (“CdS”), cadmium telluride (“CdTe”), cadmium selenide (“CdSe”), zinc oxide (“ZnO”), zinc selenide (“ZnSe”), zinc sulfide (“ZnS”), zinc telluride (“ZnTe”), and the like.

In one exemplary embodiment, the n-type semiconductor layer 104 may include a mixture or a composite of an n-type organic semiconductor compound and an n-type inorganic nanoparticle semiconductor.

The p-type organic semiconductor layer 102 and the n-type semiconductor layer 104 may have a planar area ratio of about 1:1 to about 9:1. When the p-type organic semiconductor layer 102 and the n-type semiconductor layer 104 are formed within the area ratio, it is possible to improve the hole mobility and to improve the efficiency of the solar cell.

Referring again to FIG. 1, the rear electrode 106 is disposed directly on a rear surface of the p-type organic semiconductor layer 102, and the first grid electrode 108 is disposed on a rear surface of the rear electrode 106.

The rear electrode 106 includes a conductive material having a work function of about 4.3 electron volt (eV) or more, and in one exemplary embodiment, about 4.3 eV to about 5.2 eV. The conductive material of the rear electrode 106 includes a transparent conductive oxide (“TCO”) selected from the group consisting of indium tin oxide (“ITO”), indium zinc oxide (“IZO”), zinc oxide, aluminum zinc oxide (“AZO”), gallium zinc oxide (“GZO”), and a combination thereof, or nickel (Ni).

The first grid electrode 108 disposed directly on the rear electrode may include any metal as long as it has a high electrical conductivity, and it may include, for example, silver (Ag), copper (Cu), or the like.

The second grid electrode 110 is disposed directly on a rear surface of the n-type semiconductor layer 104. The second grid electrode 110 may include a metal having a work function of about 4.2 eV or less, for example, about 2.8 eV to about 4.2 eV, such as lithium (Li), lithium doped aluminum (“Li:Al”), lithium fluoride doped aluminum (“LiF:Al”), silver (Ag), aluminum (Al), calcium (Ca), magnesium (Mg), magnesium doped lithium (“Mg:Li”), magnesium doped silver (“Mg:Ag”) or the like.

When the second grid electrode 110 includes a metal having a high work function, an additional electrode (not shown) having a low work function may be further disposed on the second grid electrode 110.

In the illustrated embodiment, all of the rear electrode 106, the first grid electrode 108 and the second grid electrode 110 are disposed on the rear surface of the semiconductor substrate 101, at a rear side of the solar cell 100. No electrodes are disposed at a front side of the solar cell 100, upon which solar light is incident to the solar cell 100.

The semiconductor substrate 101 may further include an anti-reflective coating (“ARC”) 112 on the front surface, such as overlapping an entire of the front surface. The anti-reflective coating 112 includes a transparent material being capable of absorbing a small amount of light, for example silicon nitride (“SiNₓ”), silicon oxide (“SiOₓ”), silicon oxynitride (“SiOₓN_{y}”), titanium oxide (TiO₂), aluminum oxide (Al₂O₃), magnesium oxide (MgO), cerium oxide (CeO₂), or a combination thereof. The anti-reflective coating 112 may be formed in a single layer structure or multilayer structure. The anti-reflective coating 112 may have a thickness taken perpendicular to the front surface of the semiconductor substrate 101, for example, of about 200 angstroms (Å) to about 1500 angstroms (Å). The anti-reflective coating 112 may defined the frontmost layer of the solar cell 100, and provide a front surface of the solar cell 100. The anti-reflective coating 112 may decrease the reflectivity on the front surface of the solar cell surface and increase the selectivity of a predetermined wavelength region.

As stated above, an electrode is not disposed on the front surface of the solar cell, to reduce or effectively prevent the shadowing loss, so as to increase the efficiency of the solar cell.

FIG. 2 is a schematic cross-sectional view of another exemplary embodiment of a solar cell 200, according to the invention. The same descriptions as in the above embodiment will be omitted, and the same reference numerals as in the above embodiment will refer to the same constituent elements.

As shown in FIG. 2, a solar cell 200 includes a first passivation layer 114a disposed directly between the semiconductor substrate 101 and the p-type organic semiconductor layer 102, and the semiconductor substrate 101 and the n-type semiconductor layer 104. In addition, the solar cell 200 may include a second passivation layer 114b disposed directly between the semiconductor substrate 101 and the anti-reflective coating 112. The first and second passivation layers 114a and 114b may include an inorganic oxide such as intrinsic amorphous silicon, Al₂O₃, or the like. The first passivation layer 114a and/or the second passivation layer 114b may be formed in a monolayer structure or a multilayer structure. In one exemplary embodiment, an Al₂O₃ passivation layer may be disposed directly on the front surface of the semiconductor substrate 101, and an intrinsic amorphous silicon passivation layer may be disposed thereon.

Each of the first and second passivation layers 114a and 114b may have a thickness of, for example, about 5 Å to about 100 Å. The first and second passivation layers 114a and 114b may improve the voltage and the efficiency of the solar cell 200.

Similar to the solar cell 100 in FIG. 1, an electrode is not disposed on the front surface of the solar cell 200, to reduce or effectively prevent the shadowing loss, so as to increase the efficiency of the solar cell.

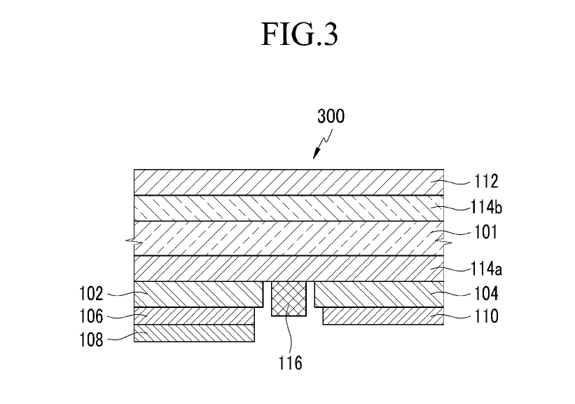

FIG. 3 is a schematic cross-sectional view of another exemplary embodiment of a solar cell 300, according to the invention. The same descriptions as in above embodiment will be omitted, and the same reference numerals as in the above embodiment will refer to the same constituent elements.

In a plan view of the solar cell 300, the p-type organic semiconductor layer 102 overlaps with and defines a first region of the solar cell 300, and the n-type semiconductor layer 104 overlaps with and defines a second region of the solar cell 300. A third region of the solar cell 300 is defined between the p-type organic semiconductor layer 102 and the n-type semiconductor layer 104, which are spaced apart from each other in the plan view.

As shown in FIG. 3, the solar cell 300 includes an insulation layer 116 disposed between the p-type organic semiconductor layer 102 and the n-type semiconductor layer 104, and within the third region of the solar cell 300. The insulation layer 116 may include acryl-based or siloxane-based organic insulating materials.

The insulation layer 116 may overlap an entire of the third region of the solar cell 300, or be disposed spaced apart from the p-type organic semiconductor layer 102 and/or the n-type semiconductor layer 104, in a direction parallel to the rear surface of the semiconductor substrate 101. The insulation layer 116 may extend from a rear surface of the first passivation layer 114a exposed in the third region of the solar cell 300, such that a rearmost surface of the solar cell 300 (e.g., a rear surface of the first grid electrode 118) is disposed further than a distal end of the insulation layer 116 is disposed.

Similar to the solar cells 100 and 200 in FIGS. 1 and 2, respectively, an electrode is not disposed on the front surface of the solar cell 300, to reduce or effectively prevent the shadowing loss, so as to increase the efficiency of the solar cell.

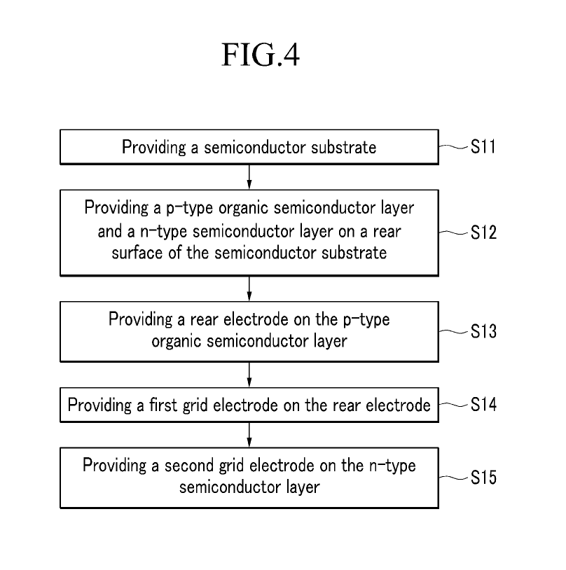

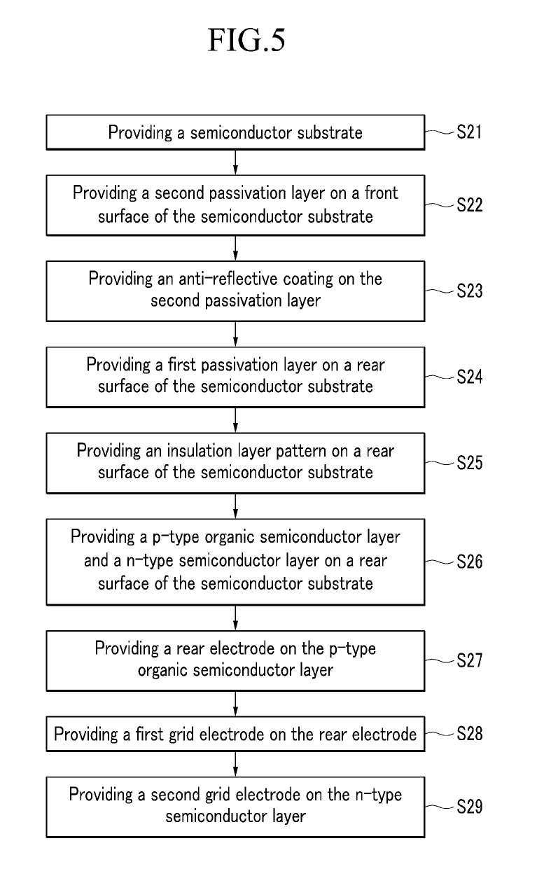

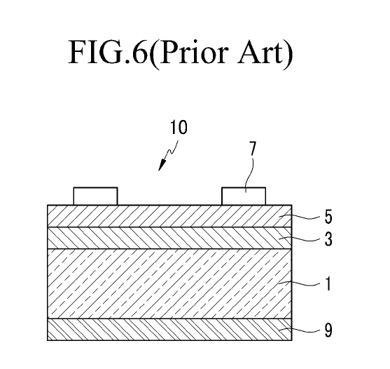

Hereinafter, an exemplary embodiment of a method of manufacturing the solar cell shown in FIG. 1 to FIG. 3, will be described with reference to FIG. 4 and FIG. 5.

FIG. 4 is a flowchart of an exemplary embodiment of a method for manufacturing a solar cell 100 shown in FIG. 1, according to the invention.

A semiconductor substrate 101 is prepared (S11). A p-type organic semiconductor layer 102 is provided on one (e.g., first) region of a rear surface of the semiconductor substrate 101 (S12). The p-type organic semiconductor layer 102 may be provided by dispersing the p-type polymer semiconductor in an organic solvent and coating the same in accordance with a wet process such as gravure printing, offset printing, screen printing, Inkjet printing, spin coating, spray coating, or the like.

A second region, different from the first region, where an n-type semiconductor layer 104 is to be provided, may be subjected to a hydrophobic treatment to prevent providing the p-type polymer semiconductor layer 102 in the second region. The hydrophobic treatment may include a fluorine-based polymer treatment, but is not limited thereto.

The n-type semiconductor layer 104 is provided disposed spaced apart from the p-type organic semiconductor layer 102 (S12). The n-type semiconductor layer 104 may be provided by dispersing the n-type semiconductor in an organic solvent to provide a composition and coating the composition in accordance with a wet process such as gravure printing, off-set printing, screen printing, Inkjet printing, spin coating, spray coating, or the like.

In an alternative embodiment, the p-type organic semiconductor layer 102 and the n-type semiconductor layer 104 may be provided in the opposite order, on the rear surface of the semiconductor substrate 101.

A rear electrode 106 is provided directly on a rear surface of the p-type organic semiconductor layer 102 (S13). The rear electrode 106 may also be provided by coating the composition in which a transparent oxide is dispersed in a solvent in accordance with a wet process such as gravure printing, off-set printing, screen printing, Inkjet printing, spin coating, spray coating, or the like.

A first grid electrode 108 is provided directly on a rear surface of the rear electrode 106 (S14). In addition, a second grid electrode 110 is provided directly on a rear surface of the n-type semiconductor layer 104 (S15). The providing order of the first grid electrode 108 and the second grid electrode 110 follows as described above, but it is not limited thereto and may be changed.

FIG. 5 is a flowchart of an exemplary embodiment of a method for manufacturing a solar cell 300 shown in FIG. 3, according to the invention. The method of providing the constituent elements having the same reference members is the same as in FIG. 4, and the same descriptions will be omitted.

A semiconductor substrate 101 is prepared (S21). A second passivation layer 114b is provided directly on a front surface of semiconductor substrate 101 (S22), and an anti-reflective coating 112 is provided directly on a front surface of the second passivation layer 114b (S23). The second passivation layer 114b and/or the anti-reflective coating 112 may be provided using sputtering, chemical vapor deposition (“CVD”), atomic layer deposition (“ALD”), or the like. In addition, the front surface of the semiconductor substrate 101 may be subjected to a surface texturing treatment before providing the second passivation layer 114b and the anti-reflective coating 112.

A first passivation layer 114a is provided directly on a rear surface of the semiconductor substrate 101 (S24). The first passivation layer 114a may be provided in accordance with the same procedure as for the second passivation layer 114b.

An insulation layer 116 is provided directly on a rear surface of the first passivation layer 114a (S25), in a third region. The insulation layer 116 may be provided by dispersing an organic insulating material in an organic solvent and patterning the same in accordance with a wet process such as gravure printing, off-set printing, screen printing, Inkjet printing, spin coating, spray coating, or the like.

A p-type organic semiconductor layer 102 is formed on one (e.g., first) region and patterned in a process similar to the insulation layer 116. An n-type semiconductor layer 104 is formed on another (e.g., second) region (S26) different from the first regions.

A rear electrode 106 and a first grid electrode 108 are subsequently formed on and overlapping the p-type organic semiconductor layer 102 (S27, S28). A second grid electrode 110 is subsequently formed on and overlapping the n-type semiconductor layer 104 (S29).

In the exemplary embodiments, the process of forming each layer on the rear surface of the semiconductor substrate 101 is carried out by the wet process, so the process is simplified and the workability is improved while the process cost is reduced. In contrast, forming the layers on the rear surface of the semiconductor substrate 101 using a photolithography process may make the process complicated and may cause an electrical short circuit between the p-type electrode and the n-type electrode, so as to deteriorate passivation quality.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate;
a p-type organic semiconductor layer disposed on a first region of a rear surface of the semiconductor substrate;
an n-type semiconductor layer disposed on a second region of the rear surface of the semiconductor substrate different than the first region;
a rear electrode disposed on the rear surface of the semiconductor substrate and overlapping the p-type organic semiconductor layer;
a first grid electrode disposed on the rear surface of the semiconductor substrate and overlapping the rear electrode; and
a second grid electrode disposed on the rear surface of the semiconductor substrate and overlapping the n-type semiconductor layer.

2. The solar cell of claim 1, wherein the semiconductor substrate comprises crystalline silicon.

3. The solar cell of claim 2, wherein the crystalline silicon comprises a monocrystalline or polysilicon wafer.

4. The solar cell of claim 1, wherein the semiconductor substrate includes a textured front surface.

5. The solar cell of claim 1, wherein the p-type organic semiconductor layer comprises at least one a p-type polymer semiconductor or a p-type organic monomolecular compound selected from the group consisting of a polyphenylene-based polymer, a polythiophene-based polymer, a polyfluorene-based polymer, a derivative thereof, a copolymer thereof, and a mixture thereof.

6. The solar cell of claim 5, wherein the p-type organic semiconductor layer comprises at least one selected from the group consisting of PPV (poly(p-phenylenevinylene)), MEH-PPV (poly(2-methoxy-5-(2′-ethyl-hexyloxy)-1,4-phenylene vinylene)), MDMO-PPV (poly(2-methoxy-5-(3,7-dimethyloctyloxy)-1,4-phenylene-vinylene)), PT (polythiophene), PEDOT (poly(3,4-ethylenedioxythiophene)), poly(3-alkylthiophene), fluorine copolymer APFO-Green1, fluorine copolymer APFO-Green2, PFDTBT (poly[2,7-(9,9′-dihexylfluorene)-alt-2,3-dimethyl-5,7-dithien-2-yl-2,1,3-benzothiadiazole]), CuPc, ZnPc, a derivative thereof, and a mixture thereof.

7. The solar cell of claim 1, wherein the n-type semiconductor layer comprises at least one selected from the group consisting of an n-type organic semiconductor compound, an n-type inorganic nanoparticle semiconductor, and a combination thereof.

8. The solar cell of claim 7, wherein the n-type organic semiconductor compound comprises at least one selected from the group consisting of fullerene, a fullerene derivative, perylene, PTCBI (3,4,9,10-perylene tetracarboxylic bis-benzimidazole), a derivative thereof, and a mixture thereof.

9. The solar cell of claim 7, wherein the n-type inorganic nanoparticle semiconductor comprises a group II-VI semiconductor compound.

10. The solar cell of claim 7, wherein the n-type inorganic nanoparticle semiconductor comprises at least one selected from the group consisting of CdS, CdTe, CdSe, ZnO, ZnSe, ZnS, ZnTe, and combinations thereof.

11. The solar cell of claim 1, wherein the rear electrode comprises a conductive material having a work function of about 4.3 electron volts (eV) or more.

12. The solar cell of claim 1, wherein the first grid electrode comprises at least one selected from the group consisting of silver, copper, and combinations thereof.

13. The solar cell of claim 1, wherein the second grid electrode comprises a metal having a work function of about 4.2 electron volts (eV) or less.

14. The solar cell of claim 13, wherein the second grid electrode is at least one selected from the group consisting of silver (Ag), copper (Cu), aluminum (Al), calcium (Ca), magnesium (Mg), Mg:Li, Mg:Ag, and combinations thereof.

15. The solar cell of claim 1, wherein the solar cell further comprises an anti-reflective coating disposed on a front surface of the semiconductor substrate.

16. The solar cell of claim 15, wherein the anti-reflective coating comprises at least one selected from the group consisting of silicon nitride (SiNₓ), silicon oxide (SiOₓ), silicon oxynitride (SiOₓN_{y}), titanium oxide (TiO₂), aluminum oxide (Al₂O₃), magnesium oxide (MgO), cerium oxide (CeO₂), and combinations thereof.

17. The solar cell of claim 1, wherein the solar cell further comprises a first passivation layer disposed between the rear surface of the semiconductor substrate and the p-type organic semiconductor layer, and the rear surface of the semiconductor substrate and the n-type semiconductor layer.

18. The solar cell of claim 17, wherein the first passivation layer comprises at least one selected from the group consisting of intrinsic amorphous silicon, Al₂O₃, and combinations thereof.

19. The solar cell of claim 1, wherein the solar cell further comprises a second passivation layer disposed on a front surface of the semiconductor substrate.

20. The solar cell of claim 19, wherein the second passivation layer comprises at least one selected from the group consisting of intrinsic amorphous silicon, Al₂O₃ and combinations thereof.

21. The solar cell of claim 1, wherein the solar cell further comprises an insulating layer disposed between the p-type organic semiconductor layer and the n-type semiconductor layer.

22. A method of manufacturing a solar cell, the method comprising:
providing a semiconductor substrate;
providing a p-type organic semiconductor layer on a first region of a rear surface of the semiconductor substrate, and providing an n-type semiconductor layer on a second region of the rear surface of the semiconductor substrate which is different than the first region;
providing a rear electrode and a first grid electrode on a rear surface of the p-type organic semiconductor layer; and
providing a second grid electrode on a rear surface of the n-type semiconductor layer.

23. The method of claim 22, further comprising sequentially providing a first passivation layer and an anti-reflective coating on a front surface of the semiconductor substrate, before the providing a p-type organic semiconductor layer on a first region of the semiconductor substrate and the providing an n-type semiconductor layer on the second region of the semiconductor substrate.

24. The method of claim 22, further comprising providing a second passivation layer on the rear surface of the semiconductor substrate, before the providing a p-type organic semiconductor layer on the first region of the semiconductor substrate and the providing an n-type semiconductor layer on the second region of the semiconductor substrate.

25. The method of claim 22, further comprising patterning and providing an insulating layer on the rear surface of the semiconductor substrate, before the providing a p-type organic semiconductor layer on the first region of the semiconductor substrate and the providing an n-type semiconductor layer on the second region of the semiconductor substrate.

26. The method of claim 25, wherein the p-type organic semiconductor layer, the n-type semiconductor layer, the rear electrode, the first and second grid electrodes, and the insulating layer are provided in accordance with a wet process.
